(19) United States
(12) Patent Application Publication
(10) Pub. No.: US 2014/0202634 A1
(43) Pub. Date: Jul. 24, 2014

(54) RADIAL TRANSMISSION LINE BASED PLASMA SOURCE

(71) Applicant: Applied Materials, Inc., Santa Clara, CA (US)

(72) Inventors: Kartik Ramaswamy, San Jose, CA (US); Steven Lane, Porterville, CA (US); Yang Yang, Los Gatos, CA (US)

(73) Assignee: APPLIED MATERIALS, INC., Santa Clara, CA (US)

(21) Appl. No.: 14/149,074

(22) Filed: Jan. 7, 2014

Related U.S. Application Data
(60) Provisional application No. 61/755,864, filed on Jan. 23, 2013.

(51) Int. Cl. H01J 37/32

(52) U.S. Cl. CPC H01J 37/32082
USPC 156/345.34; 156/345.51; 118/723 R; 315/111.21

(57) ABSTRACT

Radial transmission line based plasma sources for etch chambers are described. In an example, a radial transmission line based plasma source includes a gas delivery channel having a first end coupled to a gas inlet and having a second end coupled to a plasma showerhead. A folded or co-axial stub surrounds at least a portion of the gas delivery channel. An RF input is coupled to the folded or co-axial stub.

### CROSS-REFERENCE TO RELATED APPLICATIONS

This application claims the benefit of U.S. Provisional Application No. 61/755,864, filed on Jan. 23, 2013, the entire contents of which are hereby incorporated by reference herein.

### BACKGROUND

1) Field

Embodiments of the present invention pertain to the field of semiconductor processing and, in particular, radial transmission line based plasma sources for etch and other processing chambers.

2) Description of Related Art

For the past several decades, the scaling of features in integrated circuits has been the driving force behind an ever-growing semiconductor industry. Scaling to smaller and smaller features enables increased densities of functional units on the limited real estate of semiconductor chips. For example, shrinking transistor size allows for the incorporation of an increased number of logic and memory devices on a microprocessor, lending to the fabrication of products with increased complexity. Scaling has not been without consequence, however. As the dimensions of the fundamental building blocks of microelectronic circuitry are reduced and as the sheer number of fundamental building blocks fabricated in a given region is increased, the performance requirements of the equipment used to fabricate these building blocks have become exceedingly demanding.

A capacitively coupled plasma source for processing a workpiece, such as a semiconductor wafer, has a fixed impedance match element in the form of a coaxial resonator or tuning stub through which VHF power is applied to a discoid or cylindrically symmetrical overhead electrode. A VHF power generator is connected to the tuning stub at a point along its axis at which the RF impedance matches the impedance of the VHF power generator. One limitation of such a structure is that the coaxial tuning stub is exceptionally long, being on the order of a half wavelength of the VHF generator, which may be 0.93 meters for a VHF frequency of 162 MHz. Another limitation is that the plasma distribution produced by such a source tends to be skewed, or non-uniform in an azimuthal direction.

Accordingly, improvement are still needed in the evolution of plasma sources such as plasma sources for processing equipment, such as etch chambers used for semiconductor processing.

### SUMMARY

Embodiments described herein are directed to radial transmission line based plasma sources for etch and other processing chambers.

In an embodiment, a radial transmission line based plasma source includes a gas delivery channel having a first end coupled to a gas inlet and having a second end coupled to a plasma showerhead. A folded stub surrounds at least a portion of the gas delivery channel. An RF input is coupled to the folded stub.

In another embodiment, a radial transmission line based plasma source includes a gas delivery channel having a first end coupled to a gas inlet and having a second end coupled to a plasma showerhead. A co-axial stub surrounds at least a portion of the gas delivery channel. An RF input is coupled to the co-axial stub.

In another embodiment, a system for conducting a plasma processing operation includes a process chamber. A sample holder is disposed in a lower region of the process chamber. A radial transmission line based plasma source is disposed in an upper region of the process chamber, directly above the sample holder.

### BRIEF DESCRIPTION OF THE DRAWINGS

FIG. 1 is a cross-sectional view of a conventional coaxial transmission line.

FIG. 2 illustrates examples of conventional folded coaxial structures.

FIG. 3 illustrates a radial transmission line, in accordance with an embodiment of the present invention.

FIG. 4 illustrates an apparatus that involves the use of both a radial transmission line and a folded structure to arrive at a resonance, in accordance with an embodiment of the present invention.

FIG. 5 illustrates unfolding of a folded structure of a plasma generating apparatus, and the equivalent circuit, in accordance with an embodiment of the present invention.

FIG. 6 illustrates an apparatus where elements of a coaxial structure are used in addition to a radial structure, in accordance with an embodiment of the present invention.

FIG. 7 illustrates, (A) the co-axial stub structure of FIG. 6 in its unfolded state, with relative positions of zones I, II and III shown, and (B) an equivalent circuit of the unfolded co-axial stub structure of FIG. 6, which includes a capacitive equivalent and an inductive equivalent.

FIG. 8 is a photograph of a plasma formed in a radial resonator, in accordance with an embodiment of the present invention.

FIG. 9A illustrates a system in which a transmission line based plasma source may be included, in accordance with an embodiment of the present invention.

FIG. 9B illustrates another system in which a transmission line based plasma source may be included, in accordance with another embodiment of the present invention.

FIG. 10 illustrates a block diagram of an exemplary computer system, in accordance with an embodiment of the present invention.

### DETAILED DESCRIPTION

Radial transmission line based plasma sources for etch chambers are described. In the following description, numerous specific details are set forth, such as specific plasma source configurations, in order to provide a thorough understanding of embodiments of the present invention. It will be apparent to one skilled in the art that embodiments of the present invention may be practiced without these specific details. In other instances, well-known aspects, such as plasma processing schemes, are not described in detail in order to not unnecessarily obscure embodiments of the present invention. Furthermore, it is to be understood that the various embodiments shown in the Figures are illustrative representations and are not necessarily drawn to scale.

One or more embodiments described herein are directed to radial transmission line based plasma sources. Embodiments may include use of implementation of a radial resonator and/or a very high frequency (VHF) remote plasma source. Embodiments may be applicable to non-resonant remote plasma sources, plasma strip and abatement chambers, or remote plasma sources.

More generally, embodiments described herein include the fabrication of plasma sources in geometries that are physically small but electrically large, addressing frequency considerations. For example, lower frequency implies larger wavelengths and typically requires large electrical lengths. As a reference, microwave frequencies (e.g., greater than 1 GHz) have wavelengths on the order of 1 centimeter, whereas at VHF frequencies (e.g., 40-300 MHz) the wavelengths are on the order of 7.5-1 meters. Furthermore, there may be a need for design, functionality and cost benefits for delivering gas(es) to a plasma region in an electromagnetic field free region.

To provide context, past approaches have involved the use of very large structures to accommodate frequencies such as those described above. Additionally, past approaches have involved the use of DC (direct current) breaks to introduce or deliver in gas(es) and other services, rendering complicated designs. A prior design targeted at such frequency accommodation includes incorporated folded coaxial structures suitable to increase electrical lengths in a given space, e.g., as described in US patent publication 2012/0043023, entitled “Symmetric VHF Source for a Plasma Reactor,” which is incorporated by reference herein. One potential drawback to this approach, however, is a lack of very substantial electrical length increase.

Two factors that contribute to an increase in length include characteristic impedance and lengths of the fold. However, problems may arise when exploiting either of these factors. For example, the characteristic impedance between any two adjacent coaxial structures is constant. Additionally, as the number of folds increase in a given geometry, the characteristic impedance will fall between adjacent coaxial tubes and, as a result, substantial change in impedance is achieved only when the over all length continues to increase. Furthermore, there may be repercussions for voltage stand-offs since the gaps are decreased.

As employed herein, the terms azimuthal and radial are employed to signify directions in a cylindrical structure that are mutually orthogonal: the term radial signifies a direction along a radial line whose origin is the cylindrical axis of symmetry. The term azimuthal signifies a direction of travel along a circumference of the cylindrical structure. Non-uniform plasma distribution in the azimuthal direction may be referred to as skew. Plasma distribution may be skewed because of asymmetrical features of the plasma reactor, such as a bend in the coaxial tuning stub, RF-feeding of the tuning stub from one side, the presence of a slit opening in one side of the chamber wall, and the presence of a pumping port in the floor of the chamber of the plasma reactor.

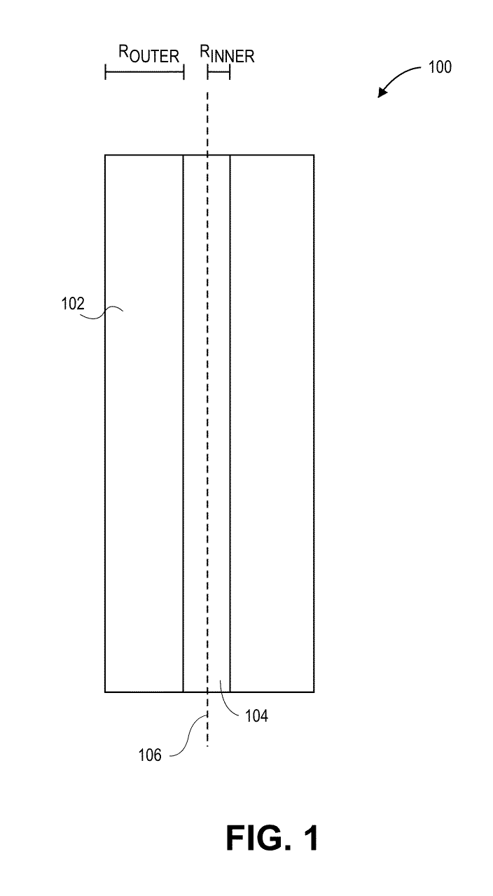

As an illustrative example, FIG. 1 is a cross-sectional view of a conventional coaxial transmission line. Referring to FIG. 1, a coaxial transmission line 100 has an outer cylindrical portion 102 with an inner opening 104. Relative to a central co-axial axis 106, the coaxial transmission line 100 has an outer radius (Rₒᵤₜₑᵣ) and an inner radius (Rᵢₙₙₑᵣ) for the cylindrical portion 102 and opening 104, respectively. In general, for a coaxial transmission line such as 100, the characteristic impedance is constant as inductance per unit length and capacitance per unit length is constant. For example, the impedance of the transmission line 100, Z₀, can be determined as 60Ln(Rₒᵤₜₑᵣ/Rᵢₙₙₑᵣ).

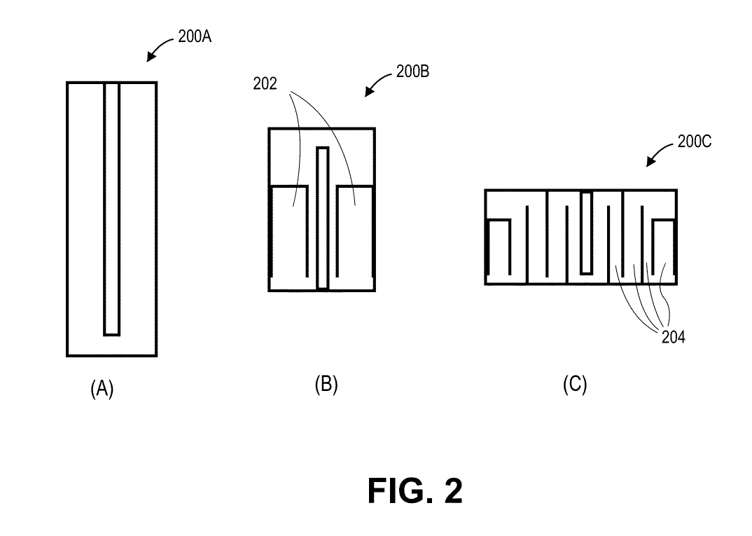

As mentioned above, in order to strike a plasma or establish a resonance at lower frequencies when restrained by geometry, a folded coaxial structure may be used. FIG. 2 illustrates examples of conventional folded coaxial structures. For example, referring to FIG. 2, example (A) a coaxial resonator 200A has no folds and is illustrated for comparative purposes. Example (B) is a coaxial resonator 200B with one fold 202. Example (C) is a coaxial resonator 200C having a plurality of folds 204.

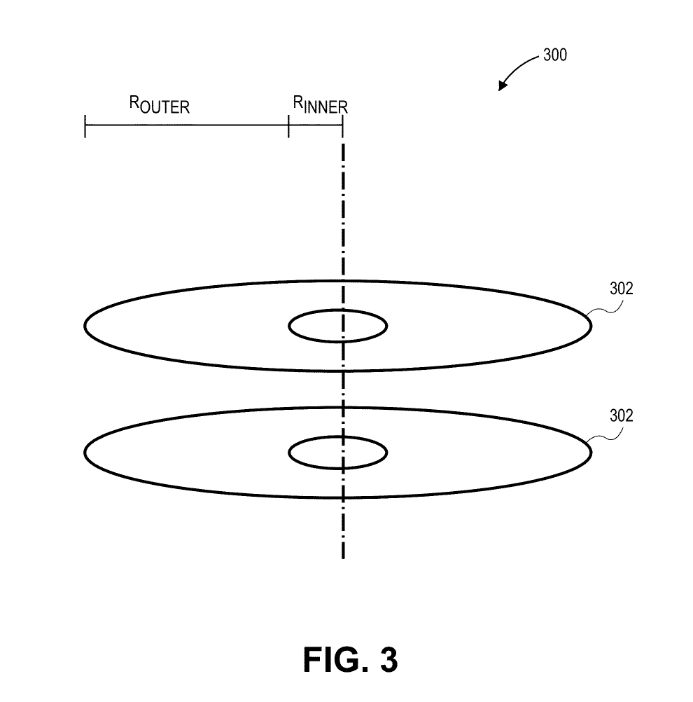

In the case that the only degree of freedom is the number of folds (i.e., length) for a coaxial transmission line, there will be limitations for many geometries. Instead, in accordance with an embodiment of the present invention, radial transmission lines are used. An example of a radial transmission line is shown in FIG. 3. Referring to FIG. 3, a radial transmission line 300 includes a plurality of structural components 302 (two are depicted in FIG. 3). The structural components 302 are aligned with one another along a central axis 302, and as such, are coaxial with one another. Each structural component 302 of the radial transmission line 300 has an outer radius (Rₒᵤₜₑᵣ) and an inner radius (Rᵢₙₙₑᵣ), which is essentially the same for each component 302, as depicted in FIG. 3. The inner radius is the radius of an opening central to each structural component 302.

In accordance with an embodiment of the present invention, a distinguishing feature of a radial transmission line, such as radial transmission line 300, is that the characteristic impedance of the transmission line is not constant. The effect is to add one more dimensionality other than folded length available to increase electrical length in a given space. As an example, in one embodiment, radially propagating transverse electromagnetic (TEM) waves are used such that little to no variation exists both axially and circumferentially. The characteristic impedance is a function of radius. In a specific embodiment Zo(r) is equal to 377*(mag(Ho(r))/magH1(r)). Here, Ho and H1 are hankel functions of the first and second order. When one end of the radial transmission line is terminated and the other end is driven (e.g., the inner and outer radius, respectively, or the outer and inner radius, respectively), the input impedance at a certain radius is given by equation (1):

Z(r)=Zo(r)[ZL Cos(θ(r)−Ψ(rL)+jZoL Sin(θ(r)−θ(rL))]/[ZoL Cos(Ψ(rL)−θ((rL))+jZL Sin(Ψ(r)−Ψ(L))], where θ(r)=angle (Ho(r)) and Ψ=angle H1(r). (1)

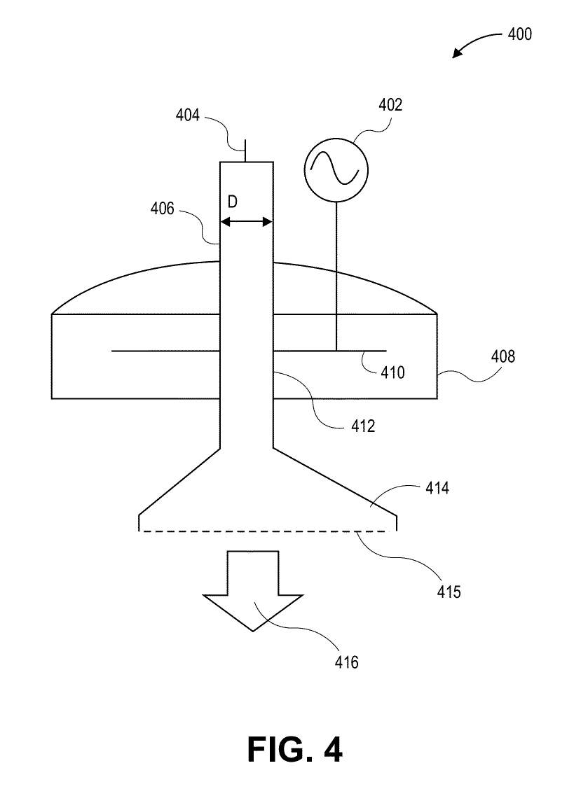

An exemplary embodiment of the present invention is depicted in FIG. 4. Referring to FIG. 4, a plasma generator or striker 400 includes an RF input 402 and a gas input 404. The gas input 404 is coupled to a delivery channel 406 which is surrounded by a folded stub 408, which may or may not be resonant. The RF input 402 is coupled to a region 410 within the folded stub 408. A dielectric window 412 separates the folded stub 408 from the delivery channel 406. The delivery channel 406 feeds into a plasma terminator and radical showerhead 414. A plasma or plasma-generated species 416 can be delivered from the plasma terminator and radical showerhead 414, e.g., for processing a substrate or wafer. In one embodiment, the plasma terminator and radical showerhead 414 includes a plasma termination mesh 415. It is to be appreciated that the diameter, D, of the delivery channel 406 can be varied, depending on application.

In an embodiment, the folded stub 408 is composed of a metal such as, but not limited to, copper or an aluminum composite alloy. In another embodiment, the folded stub 408 is composed of a printed circuit board (PCB) where routing metal layers thereon provide the needed electrical conductivity. In an embodiment, the dielectric window 412 is composed of a material such as, but not limited to, quartz, yittria, alumina, or polystyrene.

In an embodiment, operation of the plasma generator 400 of FIG. 4 involves the use of both a radial transmission line and a folded structure to arrive at a resonance. Along any radius, the impedance to the left of a chosen point is the conjugate of the impedance to the right, which is a requirement for resonance. In an embodiment, using the resonance achieved using a plasma generator such as plasma generator 400, a plasma source is fabricated wherein the energy stored in the resonator is dissipated in the generated plasma. Although a plasma termination mesh 415 is shown in FIG. 4, in other embodiments, such a mesh may not be necessary for instances where it is acceptable or desirable to expose a downstream surface to a plasma.

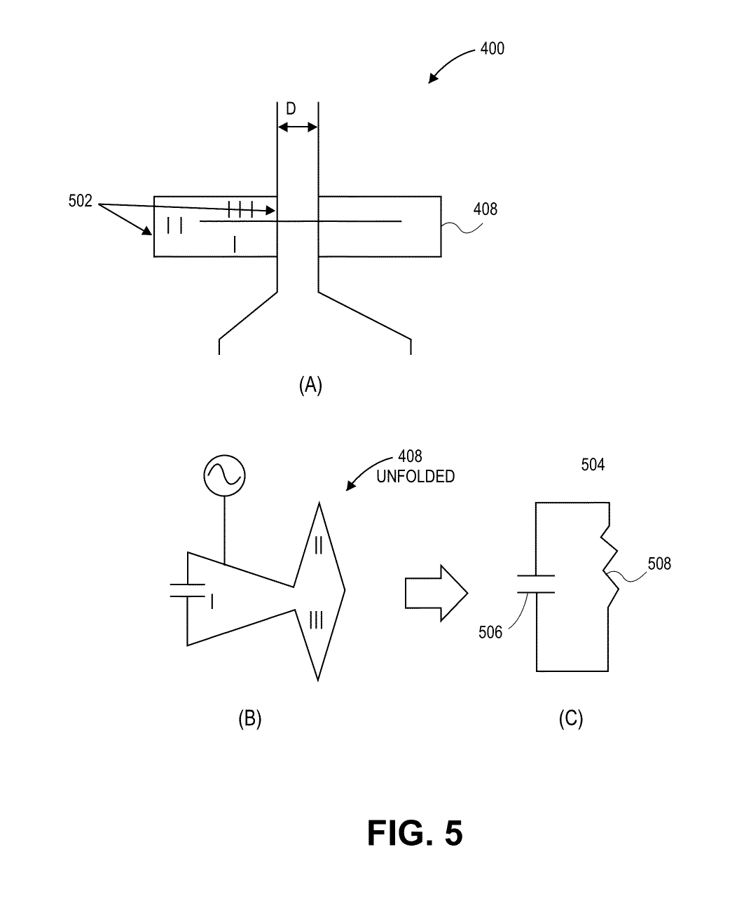

As mentioned above, the dimension, D, shown in FIG. 4 can be expanded or modified. More particularly, the diameter and spacing between the various radial transmission lines are design parameters. An example is depicted in FIG. 5, which illustrates how the folded structure unfolds, and the equivalent circuit, in accordance with an embodiment of the present invention.

Referring to FIG. 5, in part (A), relevant portions of the plasma generator 400 are depicted. For resonance, the sum of input impedance of the two shorted radial transmission lines (e.g., zone II and zone III) is the conjugate of the input impedance of the radial transmission line (zone I) with a dielectric break. The short is depicted as 502 in part (A) of FIG. 5. Although not depicted, if the structure is not resonant, an external matching circuit can be used to drive the structure. In one embodiment, the length and characteristic impedance is chosen to increase the impedance presented to the impedance tuning match. Referring to portion (B) of FIG. 5, the folded stub structure 408 of part (A) is depicted in its unfolded state, with relative positions of zones I, II and III shown. Referring to part (C) of FIG. 5, an equivalent circuit 504 of the structure 408 is depicted, which includes a capacitive equivalent 506 and an inductive equivalent 508.

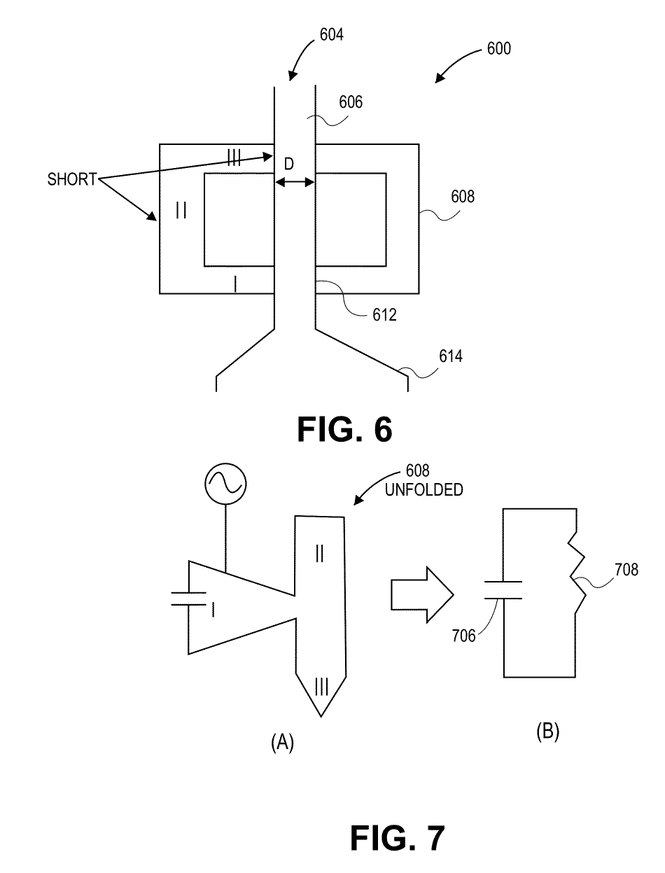

In another aspect, elements of a coaxial structure may be used in addition to a radial structure. An exemplary such embodiment of the present invention is depicted in FIG. 6. Referring to FIG. 6, a plasma generator or striker 600 includes a gas input 604. The gas input 604 is coupled to a delivery channel 606 which is surrounded by a co-axial stub 608, which may or may not be resonant. A dielectric window 612 separates the co-axial stub 608 from the delivery channel 606. The delivery channel 606 feeds into a plasma terminator and radical showerhead 614 which may or may not include a plasma termination mesh. It is to be appreciated that the diameter, D, of the delivery channel 406 can be varied, depending on application. Although not depicted, it is to be appreciated that an RF input may also be included.

In an embodiment, the co-axial stub 608 is composed of a metal such as, but not limited to, copper or an aluminum composite alloy. In another embodiment, the co-axial stub 608 is composed of a printed circuit board (PCB) where routing metal layers thereon provide the needed electrical conductivity. In an embodiment, the dielectric window 612 is composed of a material such as, but not limited to, quartz, yittria, alumina, or polystyrene.

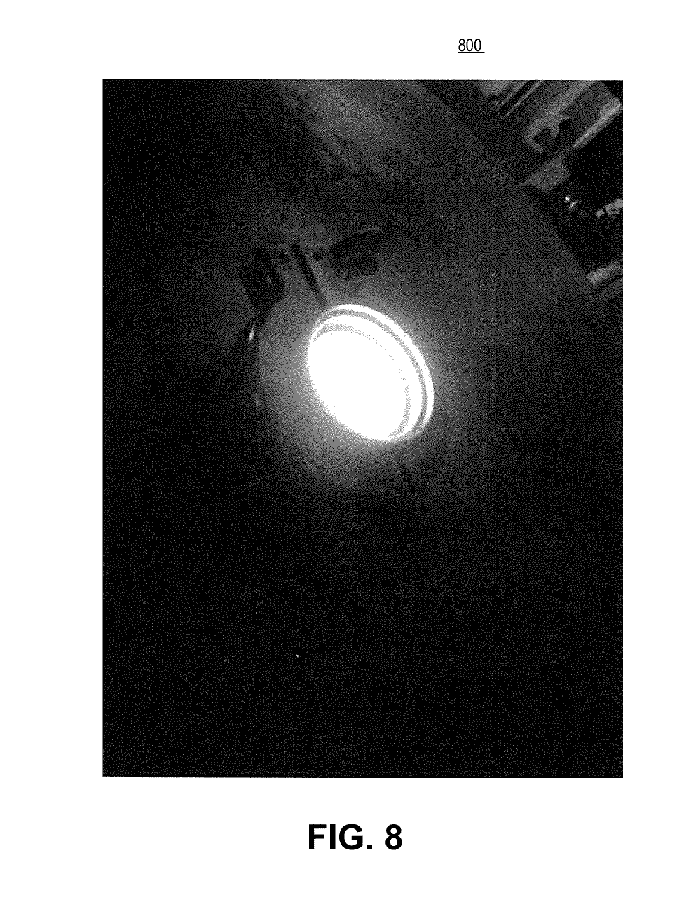

Referring again to FIG. 6, for resonance, the sum of input impedance of the two shorted radial transmission lines (e.g., zone II and zone III) is the conjugate of the input impedance of the radial transmission line (zone I) with a dielectric break. The short is depicted as 602 in FIG. 6. Although not depicted, if the structure is not resonant, an external matching circuit can be used to drive the structure. In one embodiment, the length and characteristic impedance is chosen to increase the impedance presented to the impedance tuning match. Referring to portion (A) of FIG. 7, the co-axial stub structure 608 of FIG. 6 is depicted in its unfolded state, with relative positions of zones I, II and III shown. Referring to part (B) of FIG. 7, an equivalent circuit 704 of the structure 608 is depicted, which includes a capacitive equivalent 706 and an inductive equivalent 708.

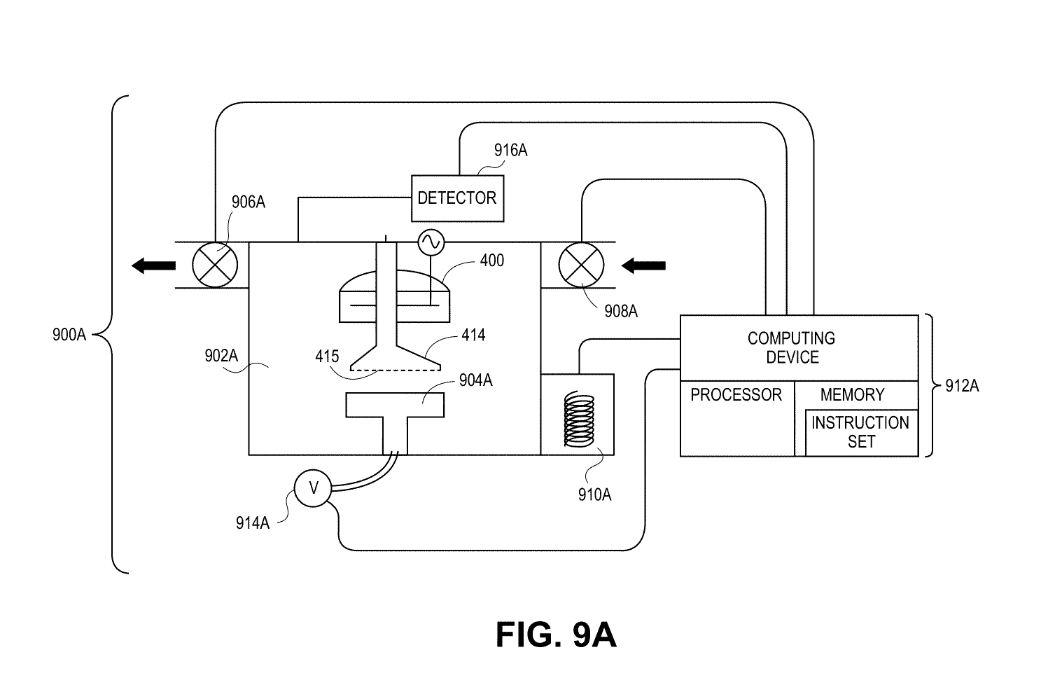

Advantages of the sources described herein may include, but are not limited to, an increased electrical length in a small physical space and the ability to introduce gases without the use of DC isolation. The described structures may only requires a small DC break, which in one embodiment, can be hidden from the plasma without the use of large ceramic windows. Such sources as those described herein can operate from very low pressures (e.g., 10 mT) to very high pressures (e.g., >2 Torr) when operated at VHF and greater frequencies. The very efficient coupling of the resonant structure enables such versatility. Also, in one embodiment, since the entire structure is at DC ground, very convenient completely DC grounded remote plasma sources can be fabricated. As an example, FIG. 8 is a photograph 800 of a plasma formed in a radial resonator, in accordance with an embodiment of the present invention.

Specifically, in an exemplary embodiment, a plasma source based on a radial transmission line was used to strip a photoresist. The etch rates were comparable to a conventional toroidal remote plasma source. More generally, embodiments of the present invention are applicable to VHF remote radical and plasma sources in a convenient grounded geometry. Furthermore, it is to be understood that the above described sources have applications not only in etch based processing, but also for chemical vapor deposition (CVD), material modifications, etc.

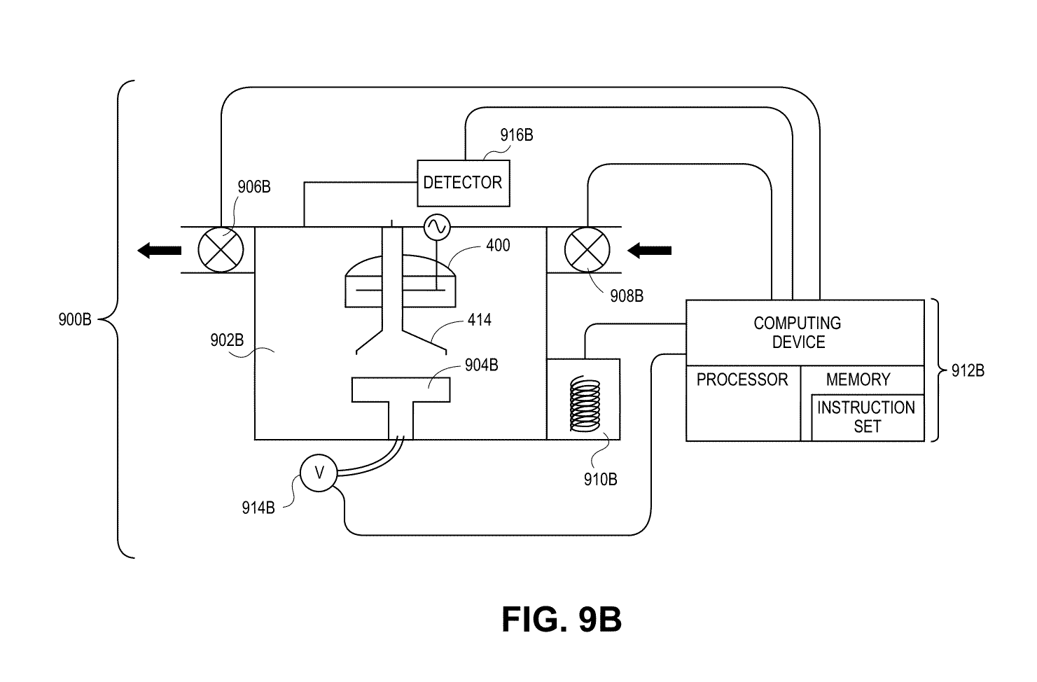

A radial transmission line based plasma source may be included in an etch, or other processing, chamber. For example, FIG. 9A illustrates a system in which a transmission line based plasma source may be included, in accordance with an embodiment of the present invention.

Referring to FIG. 9A, a system 900A for conducting a plasma etch process includes a chamber 902A equipped with a sample holder 904A. An evacuation device 906A and a gas inlet device 908A are coupled with chamber 902A. A computing device 912A is coupled with various features of the chamber. System 900A may additionally include a voltage source 914A coupled with sample holder 904A and a detector 916A coupled with chamber 902A. Computing device 912A may be coupled with evacuation device 906A, gas inlet device 908A, voltage source 914A and detector 916A, etc. as depicted in FIG. 9A. A plasma generator or striker 400, such as one of the radial transmission line based plasma sources described in association with FIG. 4, is also included. In the particular instance shown, plasma generator or striker 400 includes a plasma terminator and radical showerhead 414 and a plasma termination mesh 415. It is to be appreciated that other radial transmission line based plasma generators may instead be included, such as the plasma generator or striker 600 described in association with FIG. 6. In addition, a remote plasma source, such as plasma ignition device 910A, may also be included, depending on the application and versatility of the system.

In another example, FIG. 9B illustrates a system in which another transmission line based plasma source may be included, in accordance with another embodiment of the present invention.

Referring to FIG. 9B, a system 900B for conducting a plasma etch process includes a chamber 902B equipped with a sample holder 904B. An evacuation device 906B and a gas inlet device 908B are coupled with chamber 902B. A computing device 912B is coupled with various features of the chamber. System 900B may additionally include a voltage source 914B coupled with sample holder 904B and a detector 916B coupled with chamber 902B. Computing device 912B may be coupled with evacuation device 906B, gas inlet device 908B, voltage source 914B and detector 916B, etc. as depicted in FIG. 9B. A plasma generator or striker 400, such as one of the radial transmission line based plasma sources described in association with FIG. 4, is also included. In the particular instance shown, plasma generator or striker 400 includes a plasma terminator and radical showerhead 414, but does not include a plasma termination mesh. It is to be appreciated that other radial transmission line based plasma generators may instead be included, such as the plasma generator or striker 600 described in association with FIG. 6. In addition, a remote plasma source, such as plasma ignition device 910B, may also be included, depending on the application and versatility of the system.

Referring again to FIGS. 9A and 9B, chamber 902A or 902B and sample holder 904A or 904B may include a reaction chamber and sample positioning device suitable to contain an ionized gas, i.e. a plasma, and bring a sample in proximity to the ionized gas or charged species ejected there from. Evacuation device 906A or 906B may be a device suitable to evacuate and de-pressurize chamber 902A or 902B. Gas inlet device 908A of 908B may be a device suitable to inject a reaction gas into chamber 902A or 902B. Plasma generator or striker 400 may be a device suitable for igniting a plasma derived from the reaction gas injected into chamber 902A or 902B by gas inlet device 908A or 908B. Detection device 916A or 916B may be a device suitable to detect an end-point of a processing operation. In one embodiment, system 900A or 900B includes a chamber 902A or 902B, a sample holder 904A or 904B, an evacuation device 906A or 906B, a gas inlet device 908A or 908B, and a detector 916A or 916B similar to, or the same as, those included in an Applied Centura® Enabler dielectric etch system, an Applied Materials™ AdvantEdge G3 system, or an Applied Materials™ C3 dielectric etch chamber. It is to be appreciated that radial transmission line based plasma source may also have applications in chemical vapor deposition (CVD), atomic layer deposition (ALD), etc., processing chambers.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

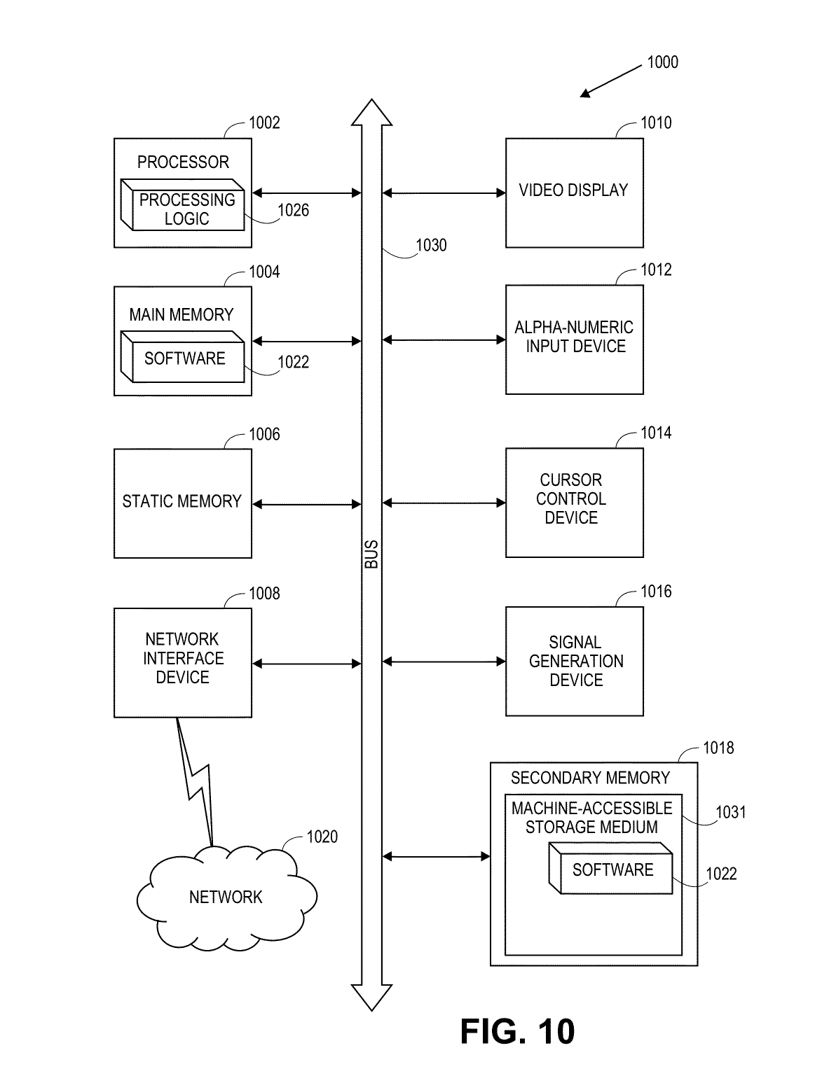

FIG. 10 illustrates a diagrammatic representation of a machine in the exemplary form of a computer system 1000 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein. In one embodiment, computer system 1000 is suitable for use as computing device 912A or 912B described in association with FIG. 9A or 9B, respectively.

The exemplary computer system 1000 includes a processor 1002, a main memory 1004 (e.g., read-only memory (ROM), flash memory, dynamic random access memory (DRAM) such as synchronous DRAM (SDRAM) or Rambus DRAM (RDRAM), etc.), a static memory 1006 (e.g., flash memory, static random access memory (SRAM), etc.), and a secondary memory 1018 (e.g., a data storage device), which communicate with each other via a bus 1030.

Processor 1002 represents one or more general-purpose processing devices such as a microprocessor, central processing unit, or the like. More particularly, the processor 1002 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 1002 may also be one or more special-purpose processing devices such as an application specific integrated circuit (ASIC), a field programmable gate array (FPGA), a digital signal processor (DSP), network processor, or the like. Processor 1002 is configured to execute the processing logic 1026 for performing the operations discussed herein.

The computer system 1000 may further include a network interface device 1008. The computer system 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse), and a signal generation device 1016 (e.g., a speaker).

The secondary memory 1018 may include a machine-accessible storage medium (or more specifically a computer-readable storage medium) 1031 on which is stored one or more sets of instructions (e.g., software 1022) embodying any one or more of the methodologies or functions described herein. The software 1022 may also reside, completely or at least partially, within the main memory 1004 and/or within the processor 1002 during execution thereof by the computer system 1000, the main memory 1004 and the processor 1002 also constituting machine-readable storage media. The software 1022 may further be transmitted or received over a network 1020 via the network interface device 1008.

While the machine-accessible storage medium 1031 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

Thus, radial transmission line based plasma sources for etch and other processing chambers have been disclosed.

What is claimed is:

1. A radial transmission line based plasma source, comprising:
a gas delivery channel having a first end coupled to a gas inlet and having a second end coupled to a plasma showerhead;
a folded stub surrounding at least a portion of the gas delivery channel; and
an RF input coupled to the folded stub.

2. The radial transmission line based plasma source of claim 1, further comprising:
a dielectric window separating a portion of the folded stub from the gas delivery channel.

3. The radial transmission line based plasma source of claim 1, wherein the plasma showerhead comprises a plasma termination mesh to confine a plasma to the radial transmission line based plasma source.

4. The radial transmission line based plasma source of claim 1, wherein the plasma showerhead does not comprise a plasma termination mesh, and the radial transmission line based plasma source is configured to deliver a plasma beyond the plasma showerhead.

5. The radial transmission line based plasma source of claim 1, wherein the folded stub is configured to be resonant.

6. The radial transmission line based plasma source of claim 1, wherein the folded stub is configured to be non-resonant.

7. The radial transmission line based plasma source of claim 1, wherein the RF input coupled to a region within the folded stub.

8. A radial transmission line based plasma source, comprising:
a gas delivery channel having a first end coupled to a gas inlet and having a second end coupled to a plasma showerhead;
a co-axial stub surrounding at least a portion of the gas delivery channel; and
an RF input coupled to the co-axial stub.

9. The radial transmission line based plasma source of claim 8, further comprising:
a dielectric window separating a portion of the co-axial stub from the gas delivery channel.

10. The radial transmission line based plasma source of claim 8, wherein the plasma showerhead comprises a plasma termination mesh to confine a plasma to the radial transmission line based plasma source.

11. The radial transmission line based plasma source of claim 8, wherein the plasma showerhead does not comprise a plasma termination mesh, and the radial transmission line based plasma source is configured to deliver a plasma beyond the plasma showerhead.

12. The radial transmission line based plasma source of claim 8, wherein the co-axial stub is configured to be resonant.

13. The radial transmission line based plasma source of claim 8, wherein the co-axial stub is configured to be non-resonant.

14. The radial transmission line based plasma source of claim 8, wherein the RF input coupled to a region within the co-axial stub.

15. A system for conducting a plasma processing operation, the system comprising:
a process chamber;
a sample holder disposed in a lower region of the process chamber; and
a radial transmission line based plasma source disposed in an upper region of the process chamber, directly above the sample holder.

16. The system of claim 15, wherein the system is for conducting a plasma processing operation selected from the group consisting of a plasma etch operation, a plasma-based chemical vapor deposition (CVD) operation, and a plasma-based atomic layer deposition (ALD) operation.

17. The system of claim 15, wherein the radial transmission line based plasma source comprises:
a gas delivery channel having a first end coupled to a gas inlet and having a second end coupled to a plasma showerhead;
a folded stub surrounding at least a portion of the gas delivery channel; and
an RF input coupled to the folded stub.

18. The system of claim 17, wherein the plasma showerhead of the radial transmission line based plasma source comprises a plasma termination mesh to confine a plasma to the radial transmission line based plasma source, away from the sample holder.

19. The system of claim 15, wherein the radial transmission line based plasma source comprises:
a gas delivery channel having a first end coupled to a gas inlet and having a second end coupled to a plasma showerhead;
a co-axial stub surrounding at least a portion of the gas delivery channel; and
an RF input coupled to the co-axial stub.

20. The system of claim 19, wherein the plasma showerhead of the radial transmission line based plasma source comprises a plasma termination mesh to confine a plasma to the radial transmission line based plasma source, away from the sample holder.
